(19) United States
(12) Patent Application Publication
(10) Pub. No.: US 2026/0231443 A1
(43) Pub. Date: Aug. 6, 2026

(54) RESISTOR FORMED ON TYPE III-V SEMICONDUCTOR BODY

(71) Applicant: Infineon Technologies Austria AG, Villach (AT)

(72) Inventors: Bhargav Pandya, Gilbert, AZ (US); Ziyang Xiao, Phoenix, AZ (US); Ole Bethge, Villach (AT)

(21) Appl. No.: 19/043,719

(22) Filed: Feb. 3, 2025

(51) Int. Cl. H10D 1/43; H10D 30/47; H10D 62/824

(52) U.S. Cl. CPC H10D 1/43; H10D 30/476; H10D 62/824

(57) ABSTRACT

A semiconductor device includes a semiconductor body having a base substrate and an upper region of type III-V semiconductor material formed on the base substrate, the upper region having one or more heterojunction interfaces between two layers of type III-V semiconductor material, a trench that extends from an upper surface of the semiconductor body into the upper region past the one or more heterojunction interfaces; and a resistor having a strip of type III-V semiconductor material formed within the trench.

### TECHNICAL FIELD

The instant application relates to semiconductor devices, and particularly relates to devices formed in type III-V semiconductor technology.

### BACKGROUND

HEMTs (high-electron-mobility Field Effect Transistors) also known as heterostructure FETs (HFETs) and modulation-doped FET (MODFETs) offer high conduction and low losses in comparison to many conventional semiconductor transistor designs. These characteristics make HEMTs desirable in applications including, but not limited to, using as switches in power supplies and power converters, electric cars, air-conditioners, and in consumer electronics, for example. HEMTs are formed from type III-V semiconductors such as gallium nitride (GaN), gallium arsenide (GaAs), etc. In a HEMT device, the active channel of the device is provided by a two-dimensional charge carrier gas which forms near a heterojunction between two type III-V semiconductor layers. Due to the high mobility of carriers in the two-dimensional charge carrier gas, this device concept offers very low on-resistance in comparison to other device technologies. For this reason, HEMTs are popular in power switching applications, i.e., applications involving the switching of voltages of at least 250V, 500V, 1000V, etc. or greater, and/or currents of at least 1 A, 5 A, 10 A, etc. or greater.

In many power switching applications, one or more passive components, e.g., capacitors, inductors, resistors, etc. may be provided in the same circuit as the power switching device. These passive components can be used for a variety of functions including, e.g., voltage dividers, load balancing, noise filtering, etc. It is desirable to provide at least some of these passive components onto the same semiconductor die as the transistor device so as to minimize parasitic effects and ease of use. However, incorporating passive components onto a semiconductor substrate that includes heterojunctions of type III-V semiconductors and is operated at substantial voltage gradients presents design challenges. In particular, leakage paths and charge traps exist within the semiconductor substrate that may degrade the performance of the passive components.

### SUMMARY

An embodiment of a semiconductor device comprises a semiconductor body comprising a base substrate and an upper region of type III-V semiconductor material formed on the base substrate, the upper region comprising one or more heterojunctions interfaces between two layers of type III-V semiconductor material, a trench that extends from an upper surface of the semiconductor body into the upper region past the one or more heterojunction interfaces, and a resistor comprising a strip of type III-V semiconductor material formed within the trench.

An embodiment of a semiconductor device comprises a semiconductor body comprising a base substrate and an upper region of type III-V semiconductor material formed on the base substrate, the upper region comprising one or more heterojunction interfaces, a resistor comprising a strip of type III-V semiconductor material formed over the upper region of the semiconductor body, and an electrical isolation structure disposed below the strip of type III-V semiconductor material that electrically isolates the strip of type III-V semiconductor material from the one or more heterojunction interfaces.

An embodiment of a semiconductor assembly comprises a half-bridge circuit comprising a high-side switch and a low-side switch connected in series with the half-bridge circuit, a resistor formed in a common semiconductor substrate as the high-side switch, wherein the common semiconductor substrate comprises one or more heterojunction interfaces between two layers of type III-V semiconductor material, wherein the common semiconductor substrate comprises one or both of: a trench that extends past the one or more heterojunction interfaces and includes the resistor disposed therein; and an electrical isolation structure that electrically isolates the resistor from the one or more heterojunction interfaces.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 depicts a semiconductor device comprising a high-electron mobility transistor and a resistor each being formed in a common semiconductor body, according to an embodiment.

FIG. 2 depicts a graph of non-ideal resistor behavior, according to an embodiment.

FIG. 3, which includes FIGS. 3A and 3B, depicts a lateral portion of a semiconductor body comprising a resistor, according to embodiments.

FIG. 4, which includes FIGS. 4A, 4B, 4C and 4D, depicts a lateral portion of a semiconductor body comprising a resistor, according to embodiments.

FIG. 5, which includes FIGS. 5A and 5B, depicts a lateral portion of a semiconductor body comprising a resistor, according to embodiments.

FIG. 6 depicts a lateral portion of a semiconductor body comprising a resistor, according to an embodiment.

FIG. 7, which includes FIGS. 7A, 7B and 7C, depicts a lateral portion of a semiconductor body comprising a resistor, according to embodiments.

FIG. 8, which includes FIGS. 8A and 8B, depicts a lateral portion of a semiconductor body comprising a resistor, according to embodiments.

FIG. 9, which includes FIGS. 9A, 9B and 9C, depicts a method of forming an isolation trench in a semiconductor body, according to an embodiment.

FIG. 10, which includes FIGS. 10A, 10B, 10C and 10D, depicts a method of forming an isolation trench in a semiconductor body, according to an embodiment.

FIG. 11, which includes FIGS. 11A and 11B, depicts circuit schematics of circuit comprising a half-bridge circuit and a resistor on a common substrate, according to embodiments.

### DETAILED DESCRIPTION

Embodiments of a semiconductor device that comprises a resistor formed on a semiconductor body, wherein the semiconductor body comprises at least one heterojunction interface of type III-V semiconductor material, are disclosed herein. The semiconductor device may additionally comprise a high-electron mobility transistor formed in a separate lateral portion of the semiconductor body as the resistor. Particularly in high-voltage applications, the heterojunction interface(s) of the semiconductor body can cause non-ideal behavior of the resistor. Specifically, back-gating effects and charge trapping effects that occur as the semiconductor body experiences substantial substrate voltage swings which may lead to dynamic resistance variations. The embodiments disclosed herein advantageously include features and corresponding methods for decoupling the resistor from the backgating and charge trapping effects of the heterojunction interfaces within the semiconductor body. As a result, the resistor exhibits more uniform behavior in the presence of substantial substrate voltage swings.

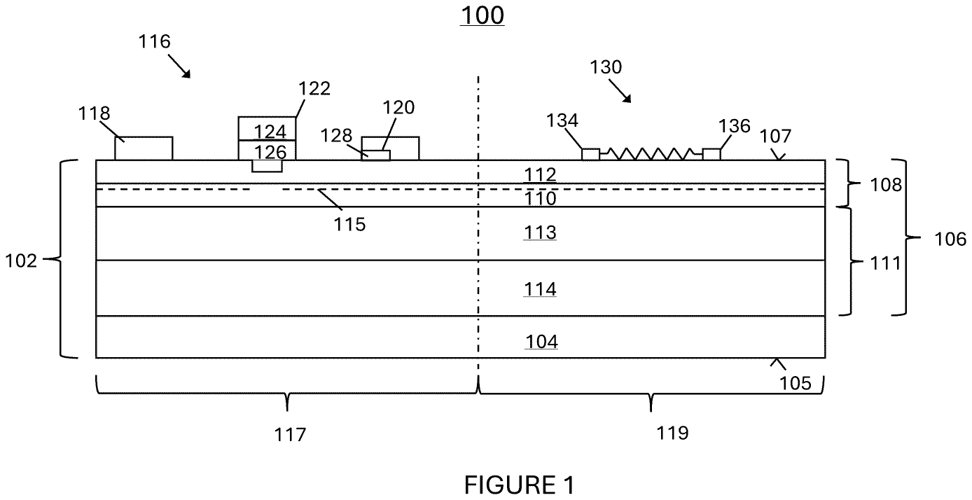

Referring to FIG. 1, a semiconductor device 100 comprises a semiconductor body 102. The semiconductor body 102 comprises a base substrate 104. The base substrate 104 forms a rear surface 105 of the semiconductor body 102 and is used as a starting substrate to epitaxially grow type III-V semiconductor material thereon. The base substrate 104 can comprise any semiconductor material that is suitable for the epitaxial formation of type III-V semiconductor material thereon. For example, the base substrate 104 may comprise materials such as silicon, sapphire, SiC (silicon carbide), carbon, diamond, GaN etc. The base substrate 104 can be provided from a commercially available wafer, such as a silicon wafer, an SOI wafer, a sapphire wafer, SiC wafer, ceramic-based substrate, etc.

The semiconductor body 102 comprises an upper region 106 of type III-V semiconductor material formed on the base substrate 104. The upper region 106 of type III-V semiconductor material comprises multiple layers of type III-V semiconductor material vertically stacked on top of one another. For example, the upper region 106 may comprise vertically stacked layers of GaN, AlGaN, InGaN, AlN, GaAs, AlGaAs, etc. These layers of type III-V semiconductor material may be formed by an epitaxial growth process. The upper region 106 of type III-V semiconductor material comprises one or more heterojunction interfaces between two layers of type III-V semiconductor material with different bandgaps. The upper region 106 of type III-V semiconductor material may also comprise one or more homojunction interfaces between two layers of type III-V semiconductor material with the same bandgap but with different dopants and/or doping concentrations.

The upper region 106 of type III-V semiconductor material comprises an active region 108. The active device channel of the high-electron mobility transistor 116 to be discussed in further detail below forms within the active region 108 forms. In the depicted embodiment, the active region 108 comprises a first layer-pair of type III-V semiconductor material that comprises a channel layer 110 and a barrier layer 112 layer formed on the channel layer 110. The channel layer 110 comprises type III-V semiconductor material with a different bandgap as the barrier layer 112. For instance, the channel layer 110 may comprise GaN or AlGaN and the barrier layer 112 may comprise AlGaN with a higher aluminum content than the channel layer 110. A naturally occurring two-dimensional charge carrier gas channel 115 arises in the channel layer 110 near the heterojunction interface between the barrier layer 112 and the channel layer 110. According to an embodiment, the two-dimensional charge carrier gas channel 115 is a two-dimensional electron gas (2DEG). Optionally, the active region 108 may comprise a spacer layer (not shown FIG. 1) in between the channel layer 110 and the barrier layer 112 of the first layer-pair. This spacer layer may be a thin layer (e.g., a 1-5 nm thick layer) of III-V semiconductor material, e.g., GaN, AlGaN, AlN, InN, InAlN, InGaN, etc.

The upper region 106 of type III-V semiconductor material comprises an intermediate region 111 of type III-V semiconductor material vertically interposed between the active region 108 and the base substrate 104. The intermediate region 111 comprises multiple layers of type III-V semiconductor material that serve different purposes. As a result, the semiconductor body 102 may comprise one or more further heterojunction interfaces at or below a lower interface of the active region 108 and an upper interface of the intermediate region 111. Optionally, the intermediate region 111 may comprise layers of electrically conductive material and/or electrically insulating material interposed between at least some of the layers of type III-V semiconductor material.

In the depicted embodiment, the intermediate region 111 comprises a back-barrier region 113 that is formed immediately underneath the active region 108. The back-barrier region 113 is configured to mitigate potential leakage paths and increase carrier confinement within the active region 108. Examples of back-barrier region configurations are disclosed in U.S. Pat. No. 10,636,899 to Curatola, the content of which is incorporated by reference herein in its entirety, and U.S. Pat. No. 10,516,023 to Curatola, the content of which is incorporated by reference herein in its entirety.

In the depicted embodiment, the intermediate region 111 comprises a lattice transition region 114 that is vertically interposed between the back-barrier region 113 and the base substrate 104. The lattice transition region 114 is configured to alleviate mechanical stress attributable to crystalline lattice mismatch between the crystal structure of the base substrate 104 and the crystal structure of the material in the active region 108, e.g., a lattice mismatch between silicon from the base substrate 104 and GaN/AlGaN material from the active region 108. As a result, the crystalline quality of the type III-V semiconductor material in the active region 108 is improved and hence the conduction characteristics of the two-dimensional charge carrier gas channel 115 is improved. The lattice transition region 114 may comprise multiple layers of type III-V semiconductor material with different alloy concentration, e.g., multiple layers of GaN/AlGaN with different aluminum content. In one particular example, the lattice transition region 114 comprises layers of type III-V semiconductor material with a graded alloy concentration, e.g., AlGaN with a gradually decreasing aluminum content moving away from the base substrate 104. Optionally, the lattice transition region 114 may comprise electrically insulating layers, e.g., layers of AlN, SiO₂ (silicon dioxide), Si₃N₄ (silicon nitride), SiO_{X}N_{Y} (silicon oxynitride), etc., interposed between the layers of type III-V semiconductor material. Examples of lattice transition regions are disclosed in U.S. Pat. No. 10,720,520 to Park, the content of which is incorporated by reference herein in its entirety, and U.S. Pat. No. 11,289,593 to Curatola, the content of which is incorporated by reference herein in its entirety.

The semiconductor device 100 comprises a high-electron mobility transistor 116 in a first lateral region 117 of the semiconductor body 102. The high-electron mobility transistor 116 comprises source and drain electrodes 118, 120 that are formed on the upper surface 107 of the semiconductor body 102. The source and drain electrodes 118, 120 are formed from an electrically conductive material, e.g., Cu, Al, and alloys thereof. The source and drain electrodes 118, 120 are each in ohmic contact with the two-dimensional charge carrier gas channel 115. The high-electron mobility transistor 116 additionally comprises a gate structure 122 that is configured to control a conductive connection between the source and drain electrodes 118, 120. The gate structure 122 comprises a gate electrode 124 that is formed from an electrical conductor such as a metal, e.g., aluminum, titanium, copper, nickel, tungsten, alloys thereof, etc., or a doped semiconductor, e.g., highly doped monocrystalline or polycrystalline semiconductors. The gate structure 122 provides on/off control of the high-electron mobility transistor 116 controlling an electric field that depletes or repopulates the two-dimensional charge carrier gas channel 115 channel underneath the gate structure 122, thereby controlling a conductive connection between the source and drain electrodes 118, 120.

In the depicted embodiment, the gate structure 122 of the high-electron mobility transistor 116 comprises a first region 126 of doped type III-V semiconductor material in between the gate electrode 124 and an upper surface 107 of the semiconductor body 102 102. According to an embodiment, the first region 126 of doped type III-V semiconductor material comprises p-type GaN or alloys thereof (e.g., p-type AlGaN). Parameters of the first region 126 of doped type III-V semiconductor material, e.g., thickness, dopant concentration, etc., may be tailored to create an electric field that locally depletes the two-dimensional charge carrier gas channel 115 channel underneath the gate structure 122 at zero-gate-source bias, thereby providing a normally-off device configuration for the high-electron mobility transistor 116. This device configuration may also be referred to as a gate injection transistor (GIT). As shown, the gate structure 122 may be configured such that the first region 126 of doped type III-V semiconductor material is arranged within a trench, thereby bringing the first region 126 of doped type III-V semiconductor material closer to the two-dimensional charge carrier gas channel 115 to facilitate enhancement mode operation. Alternatively, this trench may be omitted if the barrier layer 112 has a sufficiently low thickness to facilitate enhancement mode operation.

In the depicted embodiment, the drain structure of the high-electron mobility transistor 116 comprises a second region 128 of doped type III-V semiconductor material in between the drain electrode 120 and the semiconductor body 102. According to an embodiment, the second region 128 of doped type III-V semiconductor material comprises p-type GaN or alloys thereof (e.g., p-type AlGaN). This creates a so-called hybrid-drain HEMT gate injection transistor (GIT), which mitigates dynamic RDSON (drain-source on-resistance) effects and produces fast switching times but requires a constant gate current to maintain the device in the on-state.

The semiconductor device 100 comprises a resistor 130 disposed in a second lateral region 119 of the semiconductor body 102. The resistor 130 comprises a defined electrical resistance between first and second electrodes 134, 136 that are electrically accessible. The resistor 130 is schematically depicted in FIG. 1. The resistor 130 may comprise an electrically resistive structure disposed on the upper surface 107 of the semiconductor body 102 and/or within the semiconductor body 102 that is connected between the first and second electrodes 134, 136 and disposed above subjacent heterojunction interfaces within the semiconductor body, including the heterojunction interface between the barrier layer 112 and the channel layer 110.

The high-electron mobility transistor 116 illustrated in FIG. 1 represents just one example of a high-electron mobility transistor device that may be monolithically integrated in the same semiconductor body 102 as a resistor 130. Examples of other high-electron mobility transistor devices that may be integrated in the same semiconductor body 102 as the resistor 130 include configurations in which the gate is insulated from the semiconductor body 102 (MISHEMT devices) and configurations wherein the device does not have a hybrid-drain structure and instead includes a purely ohmic drain connection. Separately or in combination, the semiconductor body 102 may comprise a plurality of layer-pairs of the barrier layer 112 and the channel layer 110 as described above, with or without an optional spacer layer within these layer-pairs, and the high-electron mobility transistor formed within the first lateral region 117 may be a multi-channel high-electron mobility transistor device that is configured to control multiple two-dimensional charge carrier gas channels connected in parallel between the source and drain. Examples of multi-channel high-electron mobility transistors are disclosed in U.S. Pat. No. 9,035,355 to Ostermaier, the content of which is incorporated by reference herein in its entirety, U.S. Pat. No. 9,647,104 to Ostermaier, the content of which is incorporated by reference herein in its entirety, and U.S. Pat. No. 11,257,941 to Detzel, the content of which is incorporated by reference herein in its entirety.

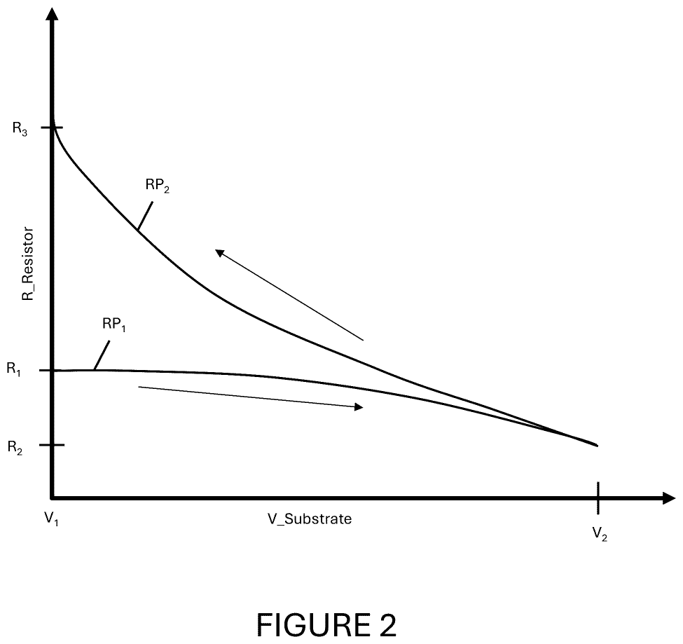

Referring to FIG. 2, a resistance of the resistor 130 (R_Resistor) in the semiconductor device 100 of FIG. 1 is plotted as a function of substrate voltage (V_Substrate). In this plot, the substrate voltage, i.e., a potential difference between the upper surface 107 of the semiconductor body 102 and the base substrate 104, is swept between an initial value V₁ to a stress-condition value V₂ as represented on the x-axis. In the first curve R_{P1}, the substrate voltage of a previously unbiased semiconductor body 102 is swept from the initial value V₁ to the stress-condition value V₂ and the resultant resistance value of the resistor 130 is plotted on the y-axis. In the second curve R_{P2}, the substrate voltage of the biased semiconductor body 102 is relaxed from the stress-condition value V₂ to the initial value V₁ and the resultant resistance value of the resistor 130 is plotted on the y-axis. As represented by the first curve R_{P1}, the resistance of the resistor 130 changes from a first resistance value R₁ to a second resistance value R₂ that is lower than the first resistance value R₁ as the substrate voltage is swept between the initial value V₁ and the stress-condition value V₂. As represented by the second curve R_{P2}, the resistance of the resistor 130 changes from the second resistance value R₂ to a third resistance value R₃ that higher than the first resistance value R₁ as the substrate voltage is relaxed from the stress-condition value V₂ to the initial value V₁.

As can be appreciated from FIG. 2, the resistor 130 exhibits non-ideal substrate voltage-dependent resistance behavior in two regards. Firstly, as represented by the first curve R_{P1}, the resistor 130 exhibits non-linear resistance over a varying substrate voltage. That is, the resistance changes between R₁ and R₂ as the substrate is increasingly biased. Secondly, as represented by the second curve R_{P2}, the resistor 130 exhibits a hysteresis effect, i.e., a memory effect whereby the previous substrate-bias conditions influence the resistance of the resistor 130. That is, the resistance changes from R₁ to R₃, even though the substrate voltage is returned to its initial value V₁. In an ideal scenario, neither of these behaviors should exist such that the resistance of the resistor 130 remains at a constant value as the voltage of the substrate is swept to a high value and returned to an initial value. Voltage swings of this type are commonplace in high power applications, such as power switching applications and thus the non-ideal substrate voltage-dependent resistance shown in FIG. 2 represents a potential failure mechanism and/or performance degradation.

The non-ideal substrate voltage-dependent resistance behavior as illustrated in FIG. 2 is attributable to the fact that the resistor 130 is formed on a semiconductor body 102 with multiple heterojunction interfaces of type III-V semiconductor material. This non-ideal behavior can be attributed, at least in part, to the following. First, the resistor 130 is susceptible to the so-called back-gating effect whereby the two-dimensional charge carrier gas channels within the semiconductor body 102 provide parallel conduction paths with the strip 132 of resistive material between the first and second electrodes 134, 136. These parallel conduction paths may include both the two-dimensional charge carrier gas channel 115 which forms near the heterojunction between the channel layer 110 and the barrier layer 112 as well as parasitic two-dimensional charge carrier gas channels which form near further heterojunction interfaces beneath the active region 108, e.g., within the back-barrier region 113 or the lattice transition region 114. This back-gating effect may lower the resistance of the resistor at higher substrate voltages, as evidenced by the first curve R_{P1}. Furthermore, the semiconductor body 102 is susceptible to charge trapping due to which the carriers that are injected into the substrate at high bias conditions are unable to be removed from the substrate. This charge trapping effect may contribute to the hysteresis effect, as evidenced by the second curve R_{P2}.

The substrate voltage-dependent resistance behavior exhibited by FIG. 2 may be observed in a semiconductor device 100 wherein the substrate experiences large enough voltage swings to implicate the above-described leakage and charge trapping effects. As an example, the initial value V₁ may be 0V and the stress-condition value V₂ may be in the range of −500V to −1,000V, while the first, second and third resistance values R_{1,} R₂ and R₃ may be in the range of 2.0-2.5KΩ, 1.5-2.0KΩ, and 5.0-10.0KΩ, respectively, and a substrate voltage-dependent resistance behavior as evidenced by FIG. 2 may be observed. In practice, the amount of resistance variation both in absolute and percentage terms may depend on factors such as, number of heterojunction interfaces within the semiconductor body 102, proximity of the resistor 130 to the heterojunction interfaces, material selection of the resistor, size of the resistor material, and the voltage swing applied to the substrate.

Described below are embodiments of a semiconductor device 100 with a resistor 130 formed on a semiconductor body 102, wherein the semiconductor device 100 comprises electrical isolation features that mitigate the substrate voltage-dependent resistance behavior, as described above. In each of the following figures, only the second lateral region 119 of the semiconductor body 102 is shown. In each case, the first lateral region 117 of the semiconductor body 102 may comprise a high-electron mobility transistor or other type of III-V semiconductor device of according to any of the embodiments described herein, to the extent consistent with the figures and description.

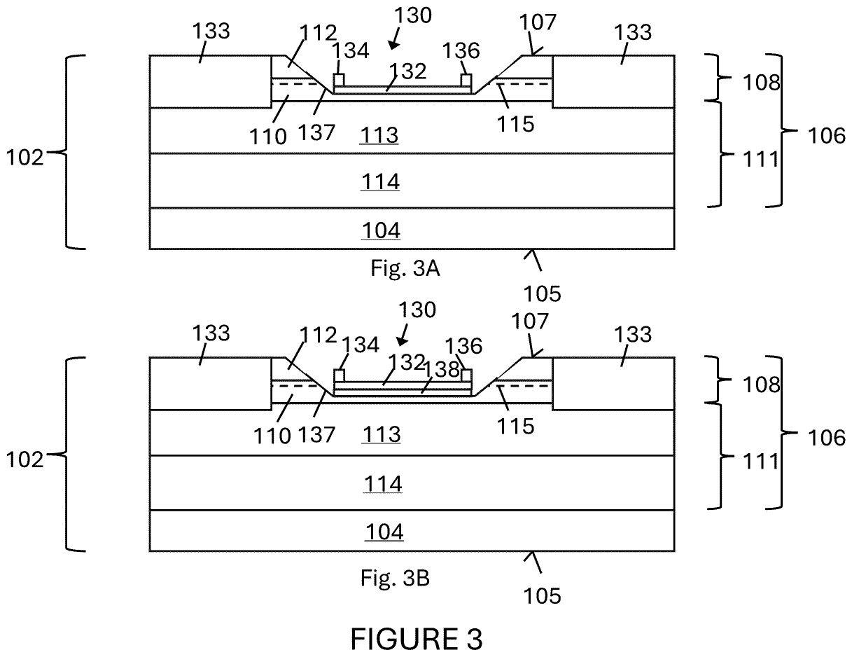

Referring to FIG. 3, a portion of a semiconductor body 102 with a resistor 130 is shown, according to embodiments. In this embodiment, the semiconductor device 100 comprises a trench 137 that extends from the upper surface 107 of the semiconductor body 102 into the upper region 106. The trench 137 comprises a bottom surface that is recessed from the upper surface 107 of the semiconductor body 102 and sidewalls that extend between the upper surface 107 and the bottom surface. In the depicted embodiment, the trench 137 has a tapered geometry such that the sidewalls are disposed at an oblique angle relative to the upper surface 107 and merge towards one another moving towards the rear surface 105 of the semiconductor body 102. In other embodiments, the sidewalls of the trench 137 may be arranged at different angles, including embodiments in which the sidewalls are perpendicular or near perpendicular to the upper surface 107 of the semiconductor body 102.

The trench 137 extends past one or more heterojunction interfaces in the semiconductor body 102. In the depicted embodiment, the trench 137 extends past the heterojunction interface between the barrier layer 112 and the channel layer 110. As a result, the two-dimensional charge carrier gas channel 115 is locally disrupted by the trench 137. In the depicted embodiment, the trench 137 terminates within the channel layer 110. As will be demonstrated by further embodiments below, the trench 137 may extend deeper into the semiconductor body 102, may terminate within a variety of different layers within the semiconductor body 102, and may extend past multiple heterojunction interfaces.

The resistor 130 is arranged such that the strip 132 of resistive material is formed within the trench 137. Specifically, the strip 132 of resistive material is formed along the bottom surface of the trench 137. The strip 132 of resistive material may comprise any type of material that can be tailored to provide a defined resistance between the first and second electrodes 134, 136. Examples materials that the strip 132 of resistive material may be formed from include type III-V semiconductor materials, such as GaN, AlGaN, AlN, InN, INAlN, and InGaN, etc. According to an embodiment, the strip 132 of type III-V semiconductor material is formed from intentionally doped III-V semiconductor material. For example, the strip 132 of type III-V semiconductor material may comprise GaN, AlGaN, etc., that is doped with any one or more of: Mg, C, Si, Ge, or Fe. The dopant concentration of the strip 132 of resistive material may be in the range of 1×10¹⁶ to 1×10²³ dopant atoms/cm³. The strip 132 of resistive material may have a majority p-type dopant concentration or a majority n-type dopant concentration. In another embodiment, the strip 132 of resistive material is formed of unintentionally doped III-V semiconductor material, e.g., unintentionally doped GaN, AlGaN, AlN, InN, INAlN, and InGaN, etc. The physical parameters of the strip 132 of resistive material including length, cross-sectional width and dopant concentration may be selected to achieve a desired nominal resistance value of the resistor 130 for a particular application. According to an embodiment, the nominal resistance value of the strip 132 of resistive material can be in the range of 1 KΩ-1 GΩ.

The first and second electrodes 134, 136 of the resistor 130 are realized by electrically conductive contact structures that are formed at opposing ends of the strip 132 of resistive material. These contact structures can comprise any of a variety of electrically conductive materials. For example, the first and second electrodes 134, 136 may each comprise Ti, Al, Cu, TiAl, TiAlCu, or any alloy thereof. According to an embodiment, the first and second electrodes 134, 136 form an ohmic, i.e., non-rectifying, connection with the strip 132 of resistive material. According to another embodiment, the first and second electrodes 134, 136 form a Schottky contact, i.e., rectifying contact, with the strip 132 of resistive material.

In the embodiment of FIG. 3A, the strip 132 of resistive material is formed directly on the bottom surface of the trench 137. In the embodiment of FIG. 3B, the resistor 130 comprises the strip 132 of resistive material and a second layer 138 interposed between the strip 132 of resistive material and the semiconductor body 102. The second layer 138 may be an electrically isolating layer that comprises, e.g., SiO₂, SiN, etc.

The trench 137 advantageously mitigates substrate voltage-dependent resistance behavior of the resistor 130 by eliminating the heterojunction interface between the barrier layer 112 and the channel layer 110 and corresponding two-dimensional charge carrier gas channel 115 channel associated with this heterojunction interface from the subjacent portion of the semiconductor body 102 beneath the resistor 130. As a result, the so-called back-gating effect as described above is mitigated, as the two-dimensional charge carrier gas channel 115 is eliminated as a potential parallel current conduction path. As a result, the resistor 130 exhibits a more linear resistance value with less dependency on the applied substrate voltage.

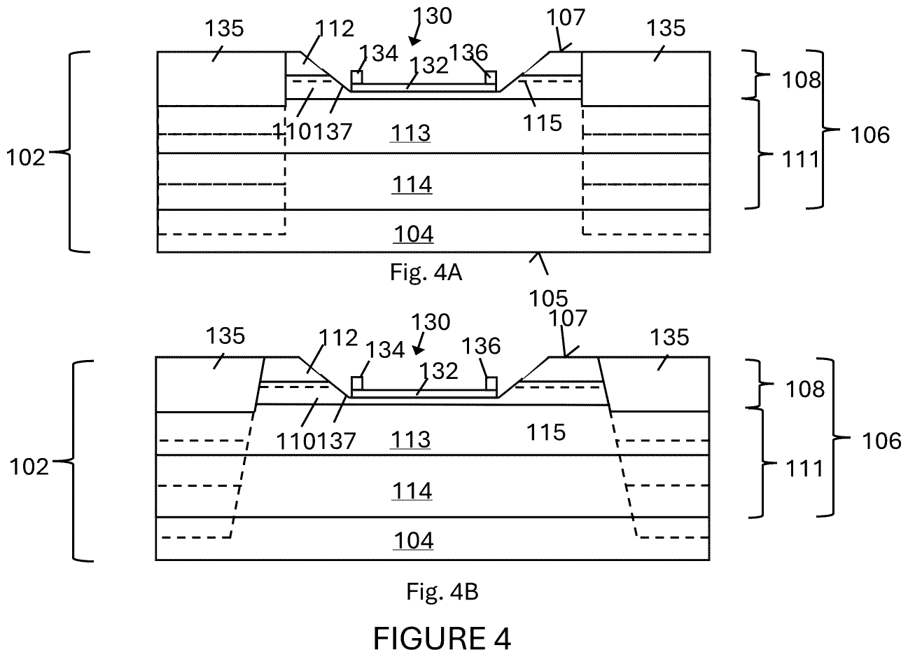

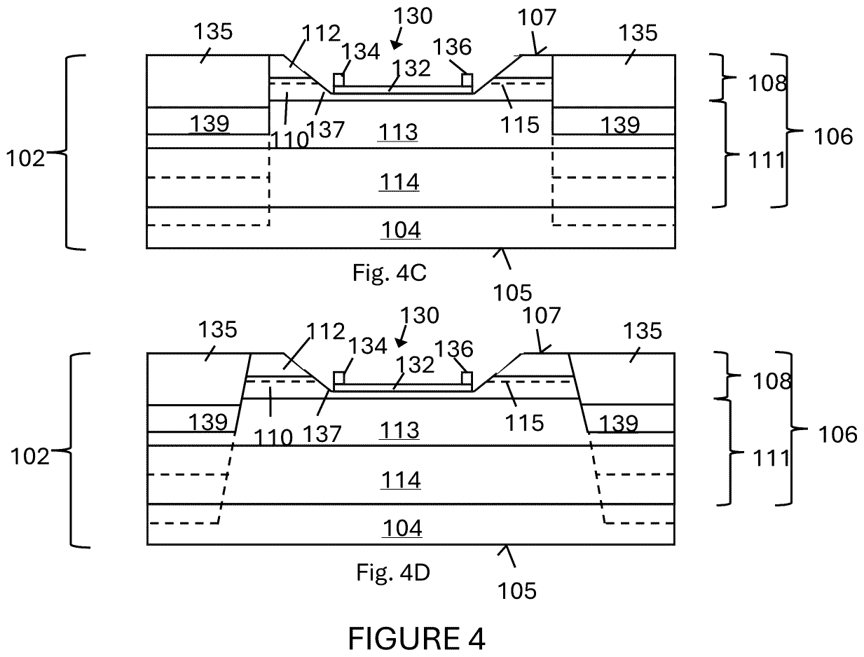

Referring to FIG. 4, various embodiments of structures for electrically isolating the second lateral region 119 from the first lateral region 117 of the semiconductor body 102 are shown. In each case, the electrical isolation structures are formed on either side of the strip 132 of resistive material and extend at least past the heterojunction interface between the barrier layer 112 and the channel layer 110, thereby isolating the two-dimensional charge carrier gas channel 115 within the second lateral region 119 from the first lateral region 117.

In the embodiments of FIGS. 4A and 4B, the isolation structures comprise first isolation regions 135 that extend from the upper surface 107 of the semiconductor body 102 towards the base substrate 104. In general, the first isolation regions 135 can be provided by any electrically isolating structure or impurity introduced into semiconductor material that decreases electrical conductivity. According to an embodiment, the first isolation regions 135 correspond to isolation implantation regions that are formed by implanting impurities that create charge trapping centers into the semiconductor material. Examples of impurities that may be implanted to create isolation implantation regions include various ions such as B+, He+, or H+, etc. According to another embodiment, the first isolation regions 135 correspond to trenches that are formed in the upper surface 107 of the semiconductor body 102. These trenches can be formed by masked etching techniques, e.g., reactive ion etching, wet chemical etching, etc., or by lift-off techniques. The trenches may be filled with one or more electrical insulators, e.g., SiO₂ (silicon dioxide), Si₃N₄ (silicon nitride), SiO_{X}N_{Y} (silicon oxynitride), etc. Alternatively, the trenches may remain unfilled.

In the embodiments of FIGS. 4C and 4D, the isolation structures additionally comprise second isolation regions 139 disposed below the first isolation regions 135. The second isolation regions 139 can be an electrically isolating structure or impurity introduced into semiconductor material in a similar manner as described above but differ in structure and/or composition from the first isolation regions 135. In one embodiment, the first isolation regions 135 are trenches that are filled with electrically insulating material, while the second isolation regions 139 are isolation implantation regions. In another embodiment, the first isolation regions 135 are unfilled trenches, and the second isolation regions 139 are isolation implantation regions.

As evidenced by the different embodiments of FIG. 4, the sidewalls of the isolation structures may be oriented at different angles. As shown in FIG. 4A, the sidewalls of the first isolation regions 135 may extend perpendicularly to the upper surface 107 of the semiconductor body 102. As shown in FIG. 4B, the sidewalls of the first isolation regions 135 may be oriented at an oblique angle relative to the upper surface 107 of the semiconductor body 102. FIGS. 4C and 4D show corresponding geometries of a combined isolation structure comprising the first isolation regions 135 and the second isolation regions 139. In the case that the isolation structures comprise a trench, the angled incline of the sidewalls may result from an anisotropic etch. In the case that the isolation structures comprise implantations, the angled incline of the sidewalls may result from an angled implantation process.

As further evidenced by the different embodiments of FIG. 4, the isolation structures may be formed to extend to a variety of different depths. In the embodiments of FIGS. 4A and 4B, the depth of the isolation structures corresponds to bottoms of the first isolation regions 135. In the embodiments of FIGS. 4C and 4D, the depth of the isolation structures corresponds to bottoms of the second isolation regions 139. In a first embodiment, the isolation structures extend into and terminate within the back-barrier region 113. In a second embodiment, the isolation structures extend into and terminate within the lattice transition region 114. In a third embodiment, the isolation structures extend into and terminate within the base substrate 104.

The various configurations of the isolation structures illustrated by FIG. 4 may further mitigate the non-ideal behavior of the resistor 130 by mitigating lateral current paths across the two-dimensional charge carrier gas channel 115 and, in the case of the deeper isolation structures, across parasitic two-dimensional charge carrier gas channels beneath the two-dimensional charge carrier gas channel 115. This may further mitigate the effects of injected carriers in the substrate subjacent to the resistor 130.

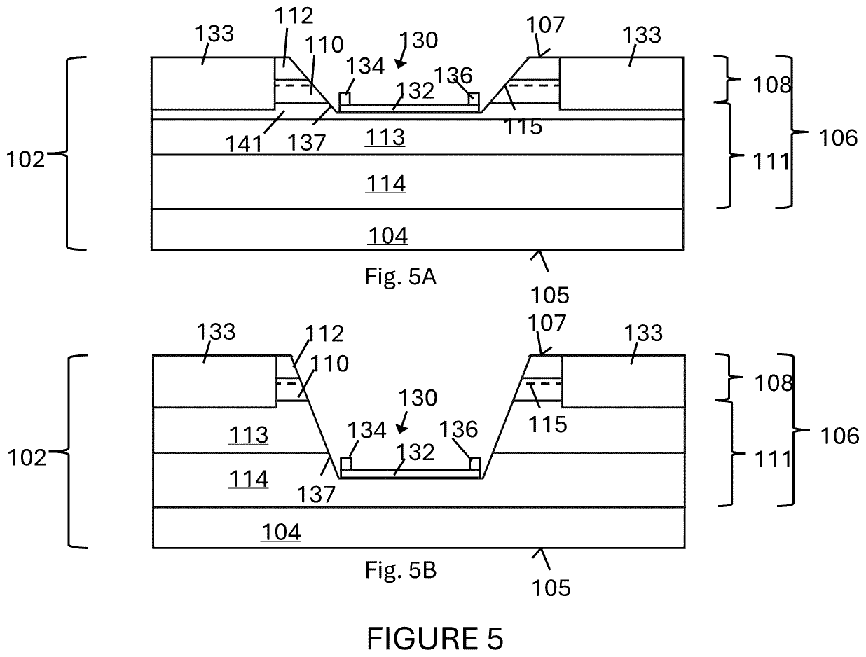

Referring to FIG. 5, a portion of a semiconductor body 102 with a resistor 130 is shown, according to embodiments. In these embodiments, the trench 137 extends past the active region 108 into the intermediate region 111 of the semiconductor body 102. As a result, the trench 137 extends past at least one further heterojunction interface that is below the heterojunction interface between the channel layer 110 and the barrier layer 112. This may further mitigate the substrate voltage-dependent resistance behavior by eliminating parasitic two-dimensional charge carrier gas channels beneath the active region 108 as potential current paths.

Referring to FIG. 5A, the trench 137 extends past the active region 108 and terminates within the back-barrier region 113 that is immediately underneath the active region 108. The trench 137 therefore extends at least past a further heterojunction interface that is between the back-barrier region 113 and a lower interface of the active region 108. As mentioned above, the back-barrier region 113 may consist of multiple layers with different composition. Generally speaking, trench 137 may terminate within any one of these layers. According to an embodiment, trench 137 terminates within an intentionally doped layer that is within the back-barrier region 113. The intentionally doped layer may comprise type III-V semiconductor material, e.g., GaN, AlGaN, etc. that is doped with impurities, e.g., C, Si, Ge, etc. The intentionally doped layer may have a dopant concentration in the range of 1×10¹⁶ to 1×10²³ dopant atoms/cm³, for example. In the depicted embodiment, trench 137 terminates within a first layer 141 which forms an uppermost layer of the back-barrier region 113. This first layer 141 may be an intentionally doped layer that is configured to increase carrier confinement within the active region 108. For example, the first layer 141 may be a layer of carbon-doped III-Nitride material, e.g., carbon doped GaN, wherein the carbon doping creates a layer of p-type material.

By terminating trench 137 within an intentionally doped layer of type III-V semiconductor material, further mitigation of the non-ideal behavior of the resistor 130 may be possible. As explained above, the non-ideal behavior of the resistor 130 can be at least partially attributed to the injection of carriers into the substrate under high substrate bias conditions. The intentionally doped layer of type III-V semiconductor material can be configured to repel these injected carriers.

In the embodiment of FIG. 5B, trench 137 extends past the active region 108 and past the back-barrier region 113 and terminates within the lattice transition region 114. As a result, trench 137 extends past multiple further heterojunction interfaces below the active region 108, and therefore eliminates multiple parasitic two-dimensional charge carrier gas channels.

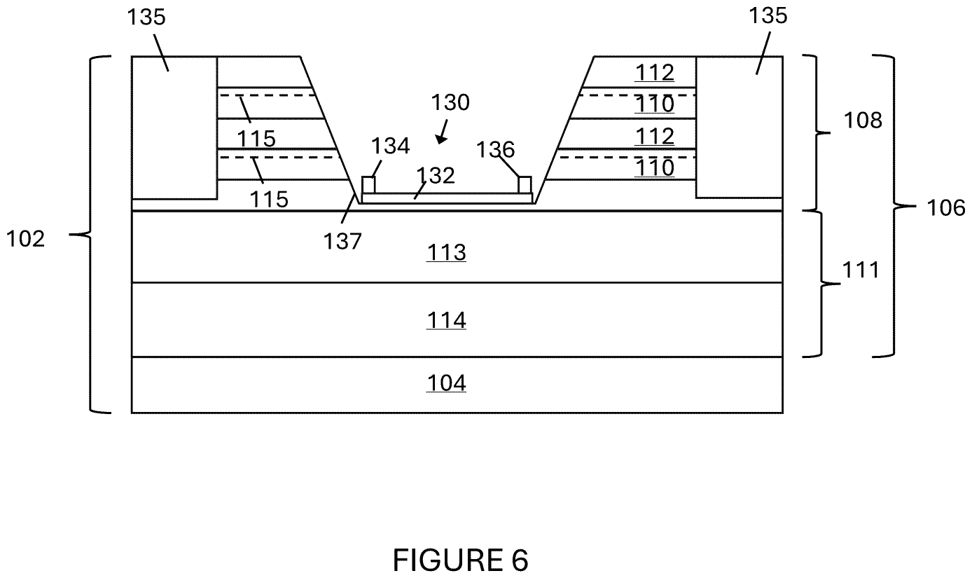

Referring to FIG. 6, a portion of a semiconductor body 102 with a resistor 130 is shown, according to an embodiment. In this embodiment, the active region 108 of the semiconductor body 102 comprises multiple layer-pairs of heterojunction forming layers. This substrate configuration may be present if the device formed in the first lateral region 117 is a multi-channel high-electron mobility transistor. As depicted, the active region 108 of the semiconductor body 102 comprises a first layer-pair of type III-V semiconductor material that comprises a channel layer 110 and a barrier layer 112 layer formed on the channel layer 110 and a second layer-pair of type III-V semiconductor material disposed below the first layer-pair of type III-V semiconductor material that comprises a second channel layer 110 and a second barrier layer 112 layer formed on the second channel layer 110. Optionally, the active region 108 may comprise a spacer layer (not shown FIG. 6) in between the channel layer 110 and the barrier layer 112 of each layer-pair. This spacer layer may be a thin layer (e.g., a 1-5 nm thick layer) of III-V semiconductor material, e.g., GaN, AlGaN, AlN, InN, InAlN, InGaN, etc.

The semiconductor device 100 is configured such that trench 137 extends past multiple heterojunction interfaces within the active region 108. As a result, trench 137 locally interrupts multiple two-dimensional charge carrier gas channels 115 and eliminates these carrier channels subjacent to the resistor 130. In the depicted embodiment, trench 137 extends completely through the active region 108 and into the back-barrier region 113, and therefore eliminates each two-dimensional charge carrier gas channels 115. More generally, trench 137 may terminate higher or lower within the semiconductor body, consistent with other embodiments disclosed herein. In the case of a device having more than two layer-pairs of type III-V semiconductor material, trench 137 may terminate within any one of these layer-pairs or may extend completely through the active region 108.

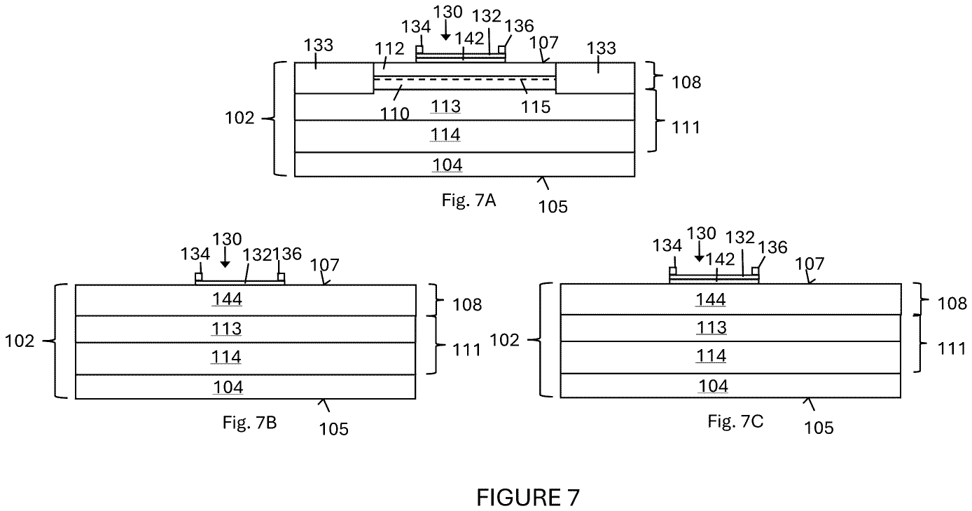

Referring to FIG. 7, a portion of a semiconductor body 102 with a resistor 130 is shown, according to embodiments. In each of these embodiments, the semiconductor device 100 is devoid of trench 137. Instead, the semiconductor device 100 comprises an electrical isolation structure disposed below the strip 132 of type III-V semiconductor material that electrically isolates the strip 132 of type III-V semiconductor material from the one or more heterojunction interfaces and consequently mitigates the potential for two-dimensional charge carrier gasses associated with these heterojunction interfaces to act as leakage paths.

In the embodiment of FIG. 7A, the semiconductor device 100 comprises an isolation layer 142 interposed between the strip 132 of resistive material and the upper surface 107 of the semiconductor body 102. The isolation layer 142 comprises an electrically insulating material such as SiO₂ (silicon dioxide), Si₃N₄ (silicon nitride), SiO_{X}N_{Y} (silicon oxynitride), etc. The isolation layer 142 provides dielectric isolation between the strip 132 of resistive material and the subjacent heterojunction interfaces, thereby mitigating the potential for parallel conduction along the two-dimensional charge carrier gas channels associated with these heterojunction interfaces.

In the embodiment of FIG. 7B, the semiconductor device 100 comprises an isolation implantation region 144. The isolation implantation region 144 is formed by implanting impurities that create charge trapping centers into the semiconductor material. The isolation implantation region 144 may be created by a blanket implantation throughout the active region 108 that extends at least to the heterojunction interface between the channel layer 110 and the barrier layer 112. For simplicity sake, the channel layer 110 and the barrier layer 112 are omitted from this figure. Examples of impurities that may be implanted to create the isolation implantation region 144 include various ions such as B+, He+, or H+, etc. In contrast to the previously described embodiments that include isolation structures 133 formed by isolation implantation, in this case the implantation is extended completely underneath the strip 132 of resistive material. The isolation implantation region 144 significantly increases the electrical resistance of the material in the vicinity of the heterojunction interface between the channel layer 110 and the barrier layer 112, and consequently reduces the effectiveness of the two-dimensional charge carrier gas channel 115 as an alternate conduction path.

In the embodiment of FIG. 7C, the electrical isolation features of the embodiments from FIGS. 7A and 7B are combined with one another. That is, the semiconductor device 100 comprises the isolation layer 142 interposed between the strip 132 of resistive material and the upper surface 107 of the semiconductor body 102 as the isolation implantation region 144 is extended completely underneath the strip 132 of resistive material.

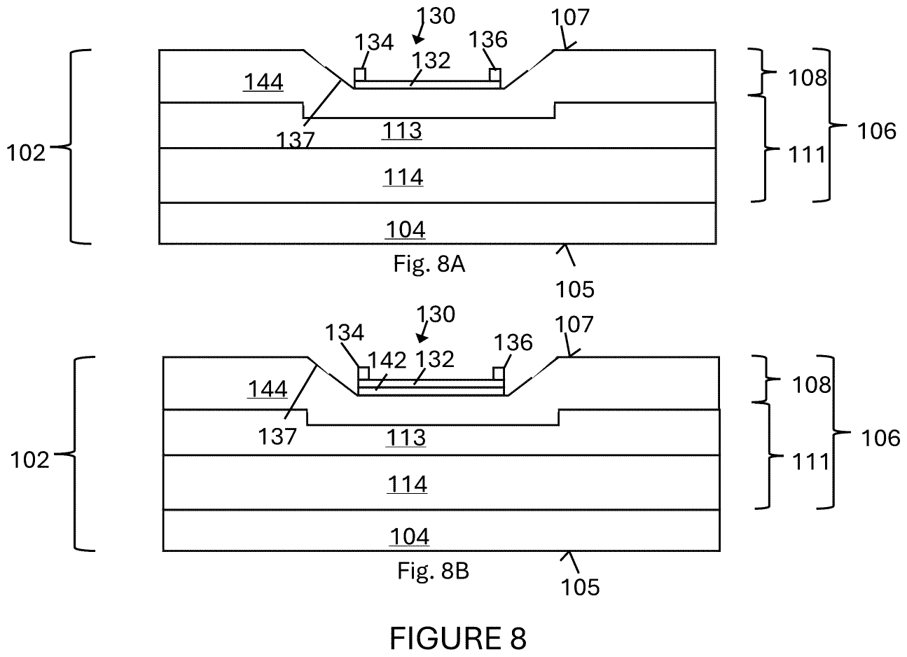

Referring to FIG. 8, an embodiment of a semiconductor device 100 with a resistor 130 is shown, according to embodiments. In each of these embodiments, the substrate voltage-dependent resistance behavior of the resistor 130 is mitigated by the combination of trench 137 and the alternate isolation features described with reference to FIG. 7. In this way, the substrate voltage-dependent resistance behavior of the resistor 130 is mitigated by the combined effect of these features.

In the embodiment of FIG. 8A, the semiconductor device 100 comprises trench 137 extending from the upper surface 107 of the semiconductor body 102 in a similar manner as described above. In this embodiment, the semiconductor device 100 comprises the isolation implantation region 144 that is extended through the second lateral region 119 including the region underneath trench 137. The isolation implantation region 144 can be formed to extend below an interface between the active region 108 and the intermediate region 111, thereby mitigating the effects of any parasitic two-dimensional charge carrier gas at this interface. The implantation step for forming the isolation implantation region 144 can be performed before or after forming trench 137.

In the embodiment of FIG. 8B, the semiconductor device 100 is similar to that of FIG. 8A, except that it additionally comprises the isolation layer 142 interposed between the strip 132 of resistive material and the bottom of trench 137. Thus, additional electrical isolation is provided.

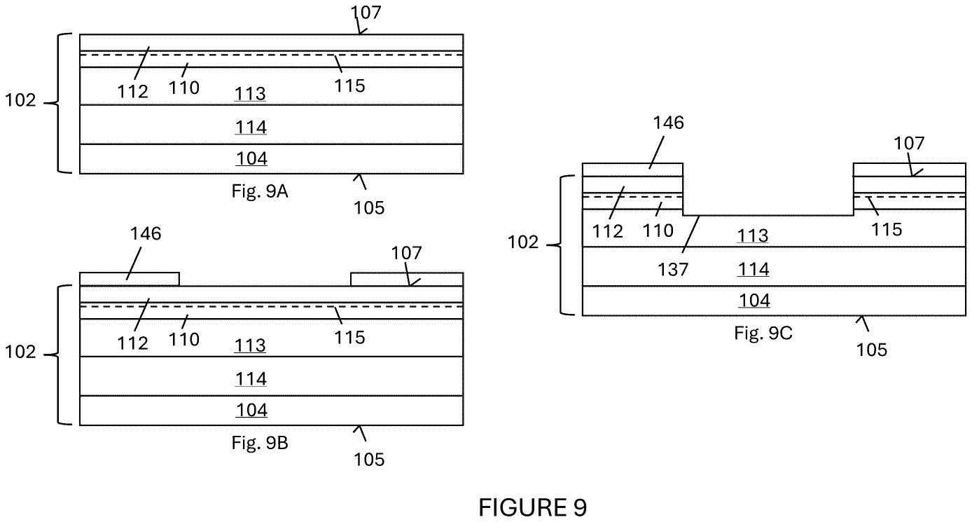

Referring to FIG. 9, selected steps in a method for forming a semiconductor device 100 are shown, according to an embodiment. These steps may be used to form trench 137 within the second lateral region 119 of the semiconductor body 102 for any of the embodiments disclosed herein. In this case, trench 137 is formed by an etching process.

Referring to FIG. 9A, the complete semiconductor body 102 as described above is initially provided. Referring to FIG. 9B, a patterned etch mask 146 is provided on the upper surface 107 of the semiconductor body 102. The patterned etch mask 146 may comprise a hardmask material such as TEOS (tetraethyl orthosilicate) that is formed by a lithographic patterning process, for example. Referring to FIG. 9C, trench 137 is formed by etching semiconductor material away from the upper surface 107 of the semiconductor body 102 selective to the material of the patterned etch mask 146. This etching process may be any kind of etching process such as an anisotropic dry etching process, wet chemical etch process, etc. In the depicted embodiment, the sidewalls of trench 137 are perpendicular to the upper surface 107 of the semiconductor body 102. As mentioned above, trench 137 may have different geometries and differently oriented sidewalls of trench 137 may be realized, e.g., through different isotropy of the etching process.

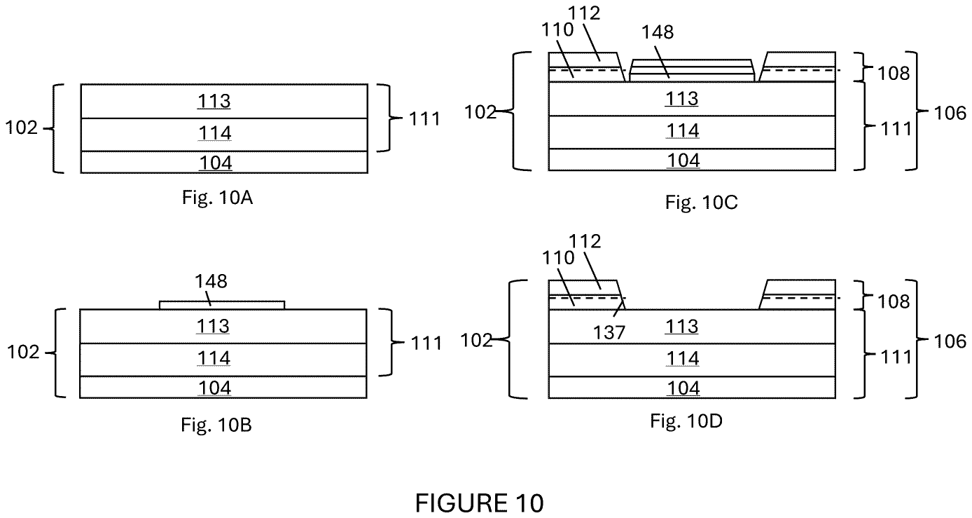

Referring to FIG. 10, selected steps in a method for forming a semiconductor device 100 are shown, according to another embodiment. These steps may be used to form trench 137 within the second lateral region 119 of the semiconductor body 102 for any of the embodiments disclosed herein. In this case, trench 137 is formed by a lift-off technique.

Referring to FIG. 10A, a partial semiconductor body 102 is provided. In this case, the partial semiconductor body 102 comprises the base substrate 104 and the intermediate region 111, as described above, while the active region 108 has not yet been formed. Referring to FIG. 10B, a lift-off layer 148 is formed on the uppermost surface of the yet-formed semiconductor body 102, i.e., the upper surface of the uppermost layer from the intermediate region 111. The lift-off layer 148 can comprise any material that is suitable for lift-off processing, e.g., LOR (lift-off resist) materials and/or PMGI Polymethylglutarimide materials. Referring to FIG. 10C, the epitaxial process is continued to form the channel layer 110 and the barrier layer 112 of the active region 108. Remnants of these layers form directly on the lift-off layer 148. Referring to FIG. 10D, the lift-off layer 148 is removed from the substrate, e.g., by dissolving, thereby removing all material formed thereon, and creating trench 137 within the active region 108. In addition to the depicted embodiment, lift-off techniques can be performed at any intermediate step or steps during the formation of the semiconductor body 102 so as to realize trench 137 at different depths.

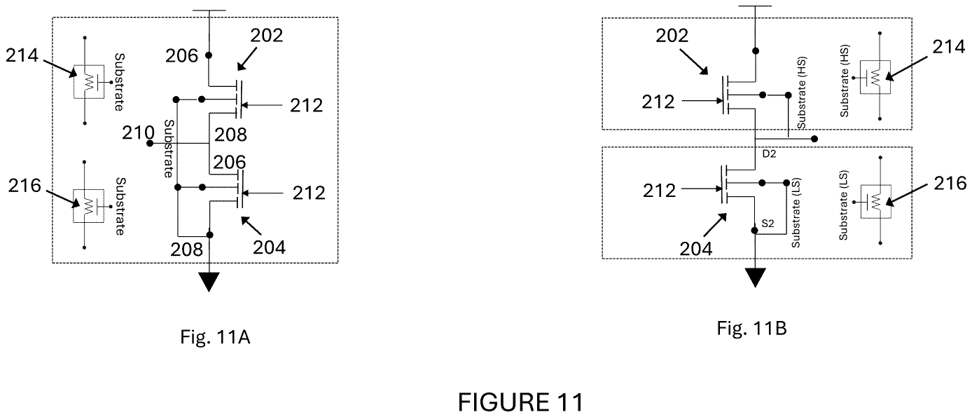

Referring to FIG. 11, embodiments of a half-bridge circuit 200 are shown. A half-bridge refers to one type of circuit topology that is used in a power conversion circuit, such as a DC-to-DC converter, DC-to-AC converter, etc. The half-bridge circuit 200 comprises a high-side switch 202 connected in series with a low-side switch 204. The drain terminal 206 of the high-side switch 202 is connected to a first DC voltage (e.g., a positive potential), the source terminal 208 of the low-side switch 204 is connected to a second DC voltage (e.g., negative potential or ground), and the source terminal 208 of the high-side switch 202 and the drain terminal 206 of the low-side switch 204 are each connected together to form the output terminal 210 of the half-bridge circuit. The gate terminals 212 of the high-side switch 202 and the low-side switch 204 can be switched according to a power control scheme (e.g., pulse width modulation) to produce a desired voltage and frequency at the output terminal 210 of the half-bridge circuit. In each of the half-bridge circuit 200 embodiments shown in FIG. 11, the half-bridge circuit 200 comprises a first resistor 214 and a second resistor 216 formed on the same substrate as the half-bridge circuit 200.

FIGS. 11A and 11B depict different substrate arrangements for the half-bridge circuit 200. In the embodiment of FIG. 11A, the high-side switch 202 and the low-side switch 204 share a common substrate. In the embodiment of FIG. 11B, the high-side switch 202 and the low-side switch 204 are provided on separate substrates.

According to an embodiment, the half-bridge circuit 200 is constructed from one or more of the semiconductor devices 100 described herein. For example, the common substrate configuration of FIG. 11A may be realized in device wherein the high-side switch 202 and the low-side switch 204 each correspond to a separate high-electron mobility transistor 116 provided in different areas of a single semiconductor body 102. In that case, the first resistor 214 and the second resistor 216 may each correspond to a resistor 130 provided in different areas of this single semiconductor body 102. In the separate substrate configuration of FIG. 11B, the high-side switch 202 may correspond to a high-electron mobility transistor 116 from a first semiconductor body 102 and the low-side switch 204 may correspond to a high-electron mobility transistor 116 from a second (separate) semiconductor body 102. In that case, the first resistor 214 and the second resistor 216 may each correspond to a resistor 130 provided in the corresponding semiconductor body 102 associated with the high-side switch 202 and the low-side switch 204, respectively.

In these embodiments, the half-bridge circuit 200 is configured such that one or both of the first resistor 214 and the second resistor 216 shares a substrate in common with the high-side switch 202. In the embodiment of FIG. 11A, each of the first and second resistors 214, 216 shares a substrate in common with the high-side switch 202. In the embodiment of FIG. 11B, the first resistor 214 shares a substrate in common with the high-side switch 202. The substrate that accommodates the high-side switch may experience substantial substrate voltage gradients during operation. The embodiments described herein advantageously protect these resistors against back-gating effects and facilitate more uniform behavior in the presence of substantial substrate voltage gradients.

In an embodiment, the semiconductor assembly comprising the half-bridge circuit 200 of FIG. 11 is a power module. In that case, the semiconductor assembly comprises an electronics carrier such as a PCB (printed circuit board), DBC (direct bonded copper) substrate, IMS (insulated substrate) substrate or AMB (active metal brazed) substrate, and the discrete transistor dies which form the high-side switch 202 and the low-side switch 204 are separately mounted on the electronics carrier. Electrical connections may be provided between the discrete transistor dies by electrical interconnect elements, e.g., metal tracks, bond wires, clips, etc. In another embodiment, the semiconductor assembly comprising the half-bridge circuit 200 of FIG. 11 is realized by one or more discrete semiconductor packages. In that case, the discrete semiconductor packages comprise a package body, e.g., a mold compound, that encapsulates one or more semiconductor dies. The semiconductor package may comprise a metal lead frame which provides the package leads and die pads. In one particular example, the discrete transistor dies which form the high-side switch 202 and the low-side switch 204 are each incorporated into the same discrete semiconductor package and internally electrically connected to one another by electrical interconnect elements, e.g., bond wires, clips, etc. In another example, the discrete transistor dies which form the high-side switch 202 and the low-side switch 204 are incorporated into separate discrete semiconductor packages. These packages may be mounted on a common carrier, such as a PCB, and electrically connected to one another by electrical interconnect elements, e.g., metal tracks, bond wires, clips, etc.

More generally, the semiconductor device 100 comprising the high-electron mobility transistor 116 and the resistor 130, according to any of the embodiments described above, may be incorporated into a wide variety of power switching circuits including half-bridge circuits, full-bridge circuits, DC-to-DC converters, DC-to-AC converters, etc., wherein a switch that experiences significant voltage gradients and a resistor device associated with the power switching circuits are provided on the same semiconductor body.

The high-electron mobility transistor described herein represents just one potential device configuration that may be monolithically integrated in a common semiconductor body with a resistor. Examples devices that may share a common semiconductor body with a resistor according to the embodiments disclosed herein include any type of III-V device including HEMT devices, e.g., thyristors, diodes, etc., as well as passive devices, e.g., capacitors, inductors, etc.

The semiconductor body disclosed herein can comprise any combination of type III-V semiconductor materials capable of forming a two-dimensional charge carrier gas channel at a heterojunction between type III-V semiconductor materials of different bandgap. These type III-V semiconductor materials include binary III-V semiconductor materials such as Gallium nitride (GaN), gallium arsenide (GaAs), aluminium nitride (AlN), aluminium arsenide (AlAs), indium nitride (InN), indium arsenide (InAs), etc., and ternary or quarternary type III-V semiconductor materials such as aluminium gallium nitride (AlGaN), aluminium gallium arsenide (AlGaAs), indium gallium nitride (InGaN), indium aluminium gallium nitride (InAlGaN), etc.

As used herein, the phrase “type III-V semiconductor material” refers to a compound material that includes at least one Group III element, such as aluminum (Al), gallium (Ga), indium (In), and boron (B) and at least one Group IV element, such as nitrogen (N), phosphorous (P), and arsenic (As), and including but not limited to any of its alloys, such as aluminum gallium nitride (AlxGa(1-x)N), indium gallium nitride (InyGa(1-y)N), aluminum indium gallium nitride (AlxInyGa(1-x-y)N), gallium arsenide phosphide nitride (GaAsaPbN(1-a-b)), and aluminum indium gallium arsenide phosphide nitride (AlxInyGa(1-x-y)AsaPbN(1-a-b)), for example. Aluminum gallium nitride and AlGaN refers to an alloy described by the formula AlxGa(1-x)N, where 0<x<1.

As used herein, the term “two-dimensional charge carrier gas channel” refers to a two-dimensional electron gas (“2DEG”) or a two-dimensional hole gas (“2DHG”).

As used herein, the description of a region “of type III-V semiconductor material” means that a substantial majority of the region in question, e.g., at least 75%, at least 80%, at least 90%, at least 95%, etc., of the region is formed of type III-V semiconductor material. A region “of type III-V semiconductor material” may include stacked layers of type III-V semiconductor material with layers of different material, e.g., electrically insulating layers, metal layers interposed between the layers of type III-V semiconductor material.

As used herein, the description that trench “terminates” within a particular layer or region means that trench enters the layer or region from above and the bottom surface of trench is spaced apart from a lower interface of the particular layer or region, such that a partial thickness of the particular layer or region exists between the bottom surface and the lower interface.

Spatially relative terms such as “under,” “below,” “lower,” “over,” “upper” and the like, are used for ease of description to explain the positioning of one element relative to a second element. These terms are intended to encompass different orientations of the device in addition to different orientations than those depicted in the figures. Further, terms such as “first,” “second,” and the like, are also used to describe various elements, regions, sections, etc. and are also not intended to be limiting. Like terms refer to like elements throughout the description.

As used herein, the terms “having,” “containing,” “including,” “comprising” and the like are open-ended terms that indicate the presence of stated elements or features, but do not preclude additional elements or features. The articles “a,” “an” and “the” are intended to include the plural as well as the singular, unless the context clearly indicates otherwise.

Although the present disclosure is not so limited, the following numbered examples demonstrate one or more aspects of the disclosure.

Example 1. A semiconductor device, comprising: a semiconductor body comprising a base substrate and an upper region of type III-V semiconductor material formed on the base substrate, the upper region comprising one or more heterojunction interfaces between two layers of type III-V semiconductor material, a trench that extends from an upper surface of the semiconductor body into the upper region past the one or more heterojunction interfaces; and a resistor comprising a strip of type III-V semiconductor material formed within the trench.

Example 2. The semiconductor device of example 1, wherein the upper region comprises an active region of type III-V semiconductor material, wherein the active region comprises a first layer-pair that comprises a first channel layer and a first barrier layer, and wherein one or more heterojunction interfaces that the trench extends past comprise a first heterojunction interface between the first channel layer and the first barrier layer.

Example 3. The semiconductor device of example 2, wherein the active region comprises a second layer-pair disposed below the first layer-pair, wherein the second layer-pair comprises a second channel layer and a second barrier layer, and wherein the one or more heterojunction interfaces that the trench extends past comprise a second heterojunction interface between the second channel layer and the second barrier layer.

Example 4. The semiconductor device of example 2, wherein the one or more heterojunction interfaces that the trench extends past comprise a further heterojunction interface, wherein the further heterojunction interface is disposed at or below a lower interface of the active region.

Example 5. The semiconductor device of example 4, wherein the semiconductor body comprises an intermediate region that is vertically interposed between the active region and the base substrate, and wherein the trench terminates within the intermediate region.

Example 6. The semiconductor device of example 5, wherein the intermediate region comprises a back-barrier region that is immediately underneath the active region, the back-barrier region is configured to increase carrier confinement within the active region, and wherein the trench terminates within the back-barrier region.

Example 7. The semiconductor device of example 5, wherein the intermediate region comprises a lattice transition region that vertically interposed between the active region and the base substrate, and wherein lattice transition region is configured to alleviate lattice mismatch between the base substrate and the active region, and wherein the trench terminates within the lattice transition region.

Example 8. The semiconductor device of example 2, wherein the trench and the resistor are disposed within a second lateral region of the semiconductor body, wherein the semiconductor device further comprises a high-electron mobility transistor disposed in a first lateral region of the semiconductor body, and wherein the high-electron mobility transistor is configured to control a conductive state of a two-dimensional charge carrier gas channel that forms in the first channel layer.

Example 9. The semiconductor device of example 8, wherein the high-electron mobility transistor is configured as a gate-injection transistor, and wherein the trench extends past the active region and terminates within a first doped layer of type III-V semiconductor material that is below the active region, and wherein the first doped layer has a conductivity type that repels injected carriers of the gate-injection transistor.

Example 10. The semiconductor device of example 8, wherein the semiconductor device comprises first isolation regions that extend from the upper surface of the semiconductor body towards the base substrate, wherein the first isolation regions laterally isolate the second lateral region from the first lateral region, and wherein the first isolation regions comprise any one or more of: isolation implantation regions, additional trenches formed in the upper surface of the semiconductor body; and regions of electrically insulating material.

Example 11. The semiconductor device of example 10, wherein the first isolation regions extend past the active region.

Example 12. The semiconductor device of example 1, wherein the strip of type III-V semiconductor material comprises intentionally doped type III-V semiconductor material.

Example 13. The semiconductor device of example 1, further comprising an isolation implantation disposed underneath the trench.

Example 14. A semiconductor device, comprising: a semiconductor body comprising a base substrate and an upper region of type III-V semiconductor material formed on the base substrate, the upper region comprising one or more heterojunction interfaces; a resistor comprising a strip of type III-V semiconductor material formed over the upper region of the semiconductor body; and an electrical isolation structure disposed below the strip of type III-V semiconductor material that electrically isolates the strip of type III-V semiconductor material from the one or more heterojunction interfaces.

Example 15. The semiconductor device of example 14, wherein the electrical isolation structure comprises a layer of electrically insulating material vertically interposed between the strip of type III-V semiconductor material and the semiconductor body.

Example 16. The semiconductor device of example 14, wherein the electrical isolation structure comprises an isolation implantation that extends completely underneath the strip of type III-V semiconductor material.

Example 17. A semiconductor assembly, comprising: a half-bridge circuit comprising a high-side switch and a low-side switch connected in series with the half-bridge circuit; and a resistor formed in a common semiconductor substrate as the high-side switch, wherein the common semiconductor substrate comprises one or more heterojunction interfaces between two layers of type III-V semiconductor material, wherein the common semiconductor substrate comprises one or both of: a trench that extends past the one or more heterojunction interfaces and includes the resistor disposed therein; and an electrical isolation structure that electrically isolates the resistor from the one or more heterojunction interfaces.

Example 18. The semiconductor assembly of example 17, wherein the resistor comprises a strip of type III-V semiconductor material formed on the common semiconductor substrate.

Example 19. The semiconductor assembly of example 17, wherein the high-side switch and the low-side switch are each formed in the common semiconductor substrate.

Example 20. The semiconductor assembly of example 17, wherein the low-side switch is provided in a separate substrate from the common semiconductor substrate.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A semiconductor device, comprising:
a semiconductor body comprising a base substrate and an upper region of type III-V semiconductor material formed on the base substrate, the upper region comprising one or more heterojunction interfaces between two layers of type III-V semiconductor material,
a trench that extends from an upper surface of the semiconductor body into the upper region past the one or more heterojunction interfaces; and
a resistor comprising a strip of type III-V semiconductor material formed within the trench.

2. The semiconductor device of claim 1, wherein the upper region comprises an active region of type III-V semiconductor material, wherein the active region comprises a first layer-pair that comprises a first channel layer and a first barrier layer, and wherein one or more heterojunction interfaces that the trench extends past comprise a first heterojunction interface between the first channel layer and the first barrier layer.

3. The semiconductor device of claim 2, wherein the active region comprises a second layer-pair disposed below the first layer-pair, wherein the second layer-pair comprises a second channel layer and a second barrier layer, and wherein the one or more heterojunction interfaces that the trench extends past comprise a second heterojunction interface between the second channel layer and the second barrier layer.

4. The semiconductor device of claim 2, wherein the one or more heterojunction interfaces that the trench extends past comprise a further heterojunction interface, wherein the further heterojunction interface is disposed at or below a lower interface of the active region.

5. The semiconductor device of claim 4, wherein the semiconductor body comprises an intermediate region that is vertically interposed between the active region and the base substrate, and wherein the trench terminates within the intermediate region.

6. The semiconductor device of claim 5, wherein the intermediate region comprises a back-barrier region that is immediately underneath the active region, the back-barrier region is configured to increase carrier confinement within the active region, and wherein the trench terminates within the back-barrier region.

7. The semiconductor device of claim 5, wherein the intermediate region comprises a lattice transition region that vertically interposed between the active region and the base substrate, and wherein lattice transition region is configured to alleviate lattice mismatch between the base substrate and the active region, and wherein the trench terminates within the lattice transition region.

8. The semiconductor device of claim 2, wherein the trench and the resistor are disposed within a second lateral region of the semiconductor body, wherein the semiconductor device further comprises a high-electron mobility transistor disposed in a first lateral region of the semiconductor body, and wherein the high-electron mobility transistor is configured to control a conductive state of a two-dimensional charge carrier gas channel that forms in the first channel layer.

9. The semiconductor device of claim 8, wherein the high-electron mobility transistor is configured as a gate-injection transistor, and wherein the trench extends past the active region and terminates within a first doped layer of type III-V semiconductor material that is below the active region, and wherein the first doped layer has a conductivity type that repels injected carriers of the gate-injection transistor.

10. The semiconductor device of claim 8, wherein the semiconductor device comprises first isolation regions that extend from the upper surface of the semiconductor body towards the base substrate, wherein the first isolation regions laterally isolate the second lateral region from the first lateral region, and wherein the first isolation regions comprise any one or more of: isolation implantation regions, additional trenches formed in the upper surface of the semiconductor body; and regions of electrically insulating material.

11. The semiconductor device of claim 10, wherein the first isolation regions extend past the active region.

12. The semiconductor device of claim 1, wherein the strip of type III-V semiconductor material comprises intentionally doped type III-V semiconductor material.

13. The semiconductor device of claim 1, further comprising an isolation implantation disposed underneath the trench.

14. A semiconductor device, comprising:
a semiconductor body comprising a base substrate and an upper region of type III-V semiconductor material formed on the base substrate, the upper region comprising one or more heterojunction interfaces;
a resistor comprising a strip of type III-V semiconductor material formed over the upper region of the semiconductor body; and
an electrical isolation structure disposed below the strip of type III-V semiconductor material that electrically isolates the strip of type III-V semiconductor material from the one or more heterojunction interfaces.

15. The semiconductor device of claim 14, wherein the electrical isolation structure comprises a layer of electrically insulating material vertically interposed between the strip of type III-V semiconductor material and the semiconductor body.

16. The semiconductor device of claim 14, wherein the electrical isolation structure comprises an isolation implantation that extends completely underneath the strip of type III-V semiconductor material.

17. A semiconductor assembly, comprising:
a half-bridge circuit comprising a high-side switch and a low-side switch connected in series with the half-bridge circuit; and
a resistor formed in a common semiconductor substrate as the high-side switch,
wherein the common semiconductor substrate comprises one or more heterojunction interfaces between two layers of type III-V semiconductor material, and
wherein the common semiconductor substrate comprises one or both of:
a trench that extends past the one or more heterojunction interfaces and includes the resistor disposed therein; and
an electrical isolation structure that electrically isolates the resistor from the one or more heterojunction interfaces.

18. The semiconductor assembly of claim 17, wherein the resistor comprises a strip of type III-V semiconductor material formed on the common semiconductor substrate.

19. The semiconductor assembly of claim 17, wherein the high-side switch and the low-side switch are each formed in the common semiconductor substrate.

20. The semiconductor assembly of claim 17, wherein the low-side switch is provided in a separate substrate from the common semiconductor substrate.
